(19) United States
(12) Patent Application Publication
(10) Pub. No.: US 2017/0102564 A1
(43) Pub. Date: Apr. 13, 2017

(54) SEMICONDUCTOR OPTICAL WAVEGUIDE, SEMICONDUCTOR OPTICAL MUDULATOR, AND SEMICONDUCTOR OPTICAL MODULATION SYSTEM

(71) Applicant: FUJIKURA LTD., Tokyo (JP)

(72) Inventors: Shinichi Sakamoto, Sakura-shi (JP); Norihiro Ishikura, Sakura-shi (JP)

(73) Assignee: FUJIKURA LTD., Tokyo (JP)

(21) Appl. No.: 15/286,687

(22) Filed: Oct. 6, 2016

(30) Foreign Application Priority Data
Oct. 9, 2015 (JP) 2015-201477

(51) Int. Cl. G02F 1/025; G02F 1/225; G02F 1/01; H01L 29/167

(52) U.S. Cl. CPC G02F 1/025; H01L 29/167; G02F 1/2257; G02F 1/2255; G02F 1/0123; G02F 2201/127; G02F 2001/212

(57) ABSTRACT

A boundary surface (12S) which divides a rib (12) of a rib-slab type core (11) into a p-type semiconductor region (12a) and an n-type semiconductor region (12b) is constituted by a first flat surface (S1) serving as a junction surface of a first lateral p-n junction (J1), a second flat surface (S2) serving as a junction surface of a vertical p-n junction (J2), and a third flat surface (S3) serving as a junction surface of a second lateral p-n junction (J3).

This Nonprovisional application claims priority under 35 U.S.C. §119 on Patent Application No. 2015-201477 filed in Japan on Oct. 9, 2015, the entire contents of which are hereby incorporated by reference.

### TECHNICAL FIELD

The present invention relates to a semiconductor optical waveguide which includes a core having a p-type semiconductor region and an n-type semiconductor region. The present invention also relates to a semiconductor optical modulator including the semiconductor optical waveguide, and a semiconductor optical modulation system including the semiconductor optical modulator.

### BACKGROUND ART

There is known a semiconductor optical waveguide having a core made of a semiconductor (e.g., silicon). It is also known that a semiconductor optical waveguide which includes a core having a p-type semiconductor region and an n-type semiconductor region functions as a phase modulator which modulates a phase of light near a junction surface of a p-n junction. A phase of light guided near the junction surface of the p-n junction is modulated in accordance with a modulation voltage, which is a voltage externally applied to both ends of the p-n junction. This semiconductor optical waveguide is used, for example, in a transmission section of a communication transceiver.

In recent years, there is a demand for communication transceivers to have lower power consumption and a wider bandwidth. In order to meet the demand, phase modulators are expected to have improved optical modulation efficiency, improved high frequency characteristics, and the like.

Patent Literature 1 describes a p-n diode optical modulator (corresponding to the semiconductor optical waveguide of the present application) which has improved optical modulation efficiency by the adoption of a p-n junction in which a boundary surface (a junction surface of the p-n junction) between a p-type semiconductor region and an n-type semiconductor region has a jagged shape (see FIG. 6 of Patent Literature 1) or a sine wave shape (see FIG. 7 of Patent Literature 1) in a plan view of the semiconductor optical waveguide.

This arrangement increases a total area of the junction surface of the p-n junction, and accordingly allows an increase in ratio of a volume of a depletion layer, which is formed near the junction surface, to a volume of an entire core. This increases the number of carriers contributing to phase modulation, and accordingly enables improvement of modulation efficiency (allows a reduction in half wavelength voltage Vpi, which is a voltage necessary in order for an optical phase shift amount to be π).

However, the semiconductor optical waveguide described in Patent Literature 1 has a problem that it is difficult to avoid deterioration of high frequency characteristics. In a semiconductor optical waveguide having a p-n junction, an increase in total area of a junction surface of the p-n junction means an increase in capacitance of the p-n junction. In the semiconductor optical waveguide described in Patent Literature 1, such an increased capacitance invites deterioration of high frequency characteristics. In other words, due to lack of consideration of high frequency characteristics, the deterioration of high frequency characteristics cannot be avoided, though the modulation efficiency can be improved, in the semiconductor optical waveguide described in Patent Literature 1. It is thus difficult to secure both modulation efficiency and high frequency characteristics in the semiconductor optical waveguide described in Patent Literature 1.

As a technique contributing to solving this problem, Patent Literature 2 describes an electro-optic silicon modulator (corresponding to the semiconductor optical waveguide of the present application) which employs a p-n junction having a different structure from those of the p-n junctions described in FIGS. 6 and 7 of Patent Literature 1.

Semiconductor optical waveguides respectively illustrated in FIGS. 1 and 2 of Patent Literature 2 are each a semiconductor optical waveguide including a rib-slab type core.

The semiconductor optical waveguide illustrated in FIG. 1 of Patent Literature 2 employs a p-n junction that is provided inside a rib and has a junction surface constituted by two flat surfaces. Among the two flat surfaces constituting the junction surface of the p-n junction, (1) a first flat surface is a flat surface which constitutes a junction surface of a lateral p-n junction, wherein a lower end of the first flat surface reaches a lower surface of the rib and (2) a second flat surface is a flat surface which constitutes a junction surface of a vertical p-n junction, wherein a left end of the second flat surface is connected to an upper end of the first flat surface and a right end of the second flat surface reaches a right side surface of the rib. That is, the semiconductor optical waveguide illustrated in FIG. 1 has a p-n junction surface with an L-shaped cross section.

The semiconductor optical waveguide illustrated in FIG. 2 of Patent Literature 2 employs a p-n junction which lies across a rib and a slab and in which a junction surface is constituted by three flat surfaces. Among the three flat surfaces constituting the junction surface, (1) a first flat surface is a flat surface which constitutes a junction surface of a lateral p-n junction, wherein an upper end of the first flat surface reaches an upper surface of the slab, (2) a second flat surface is a flat surface which constitutes a junction surface of a vertical p-n junction, wherein a right end of the second flat surface is connected to a lower end of the first flat surface, and (3) a third flat surface is a flat surface which constitutes a junction surface of another lateral p-n junction, wherein an upper end of the third flat surface is connected to a left end of the second flat surface and a lower end of the third flat surface reaches a lower surface of the rib. That is, a phase modulation section included in the semiconductor optical waveguide illustrated in FIG. 2 has a p-n junction surface with a crank-shaped cross section.

As described above, the semiconductor optical waveguide illustrated in FIG. 1 of Patent Literature 2 employs a p-n junction having a junction surface with an L-shaped cross section and the semiconductor optical waveguide illustrated in FIG. 2 of Patent Literature 2 employs a p-n junction having a junction surface with a crank-shaped cross section, when each of the semiconductor optical waveguides is viewed from a direction in which light is guided through the core.

These p-n junctions are considered to allow improved modulation efficiency without increasing total areas of the p-n junctions, as compared respectively with (i) a lateral p-n junction in which a boundary surface between a p-type semiconductor region and an n-type semiconductor region extends from an upper surface to a lower surface of a rib and (ii) a vertical p-n junction in which a boundary surface between a p-type semiconductor region and an n-type semiconductor region extends from a left side surface to a right side surface of a rib. That is, the semiconductor optical waveguides illustrated in FIGS. 1 and 2 of Patent Literature 2 are each considered an effective technique for securing both modulation efficiency and high frequency characteristics.

### CITATION LIST

### Patent Literature

[Patent Literature 1]

U.S. Pat. No. 7,136,544 [Registration Date: Nov. 14, 2006]

[Patent Literature 2]

U.S. Pat. No. 8,149,493 [Registration Date: Apr. 3, 2012]

### SUMMARY OF INVENTION

### Technical Problem

However, since the p-n junction provided in the rib of the semiconductor optical waveguide illustrated in FIG. 1 of Patent Literature 2 is arranged such that the second flat surface serving as the junction surface of the vertical p-n junction reaches the right side surface of the rib, it is inevitable that a portion of the second flat surface near the right end thereof is in a region having a very low optical density among an inner region of the rib. This is because a width-direction optical density of light that is guided in the core is the highest at a center of the rib and gradually decreases in a direction away from the center of the rib.

As described above, the semiconductor optical waveguide illustrated in FIG. 1 of Patent Literature 2 has an increased total area of the junction surface due to the L-shape of the junction surface of the p-n junction provided in the rib, but the increase in total area is not used efficiently for the improvement of modulation efficiency.

Further, in the p-n junction provided in the rib of the semiconductor optical waveguide illustrated in FIG. 2 of Patent Literature 2, the first flat surface, which serves as the junction surface of the lateral p-n junction, is provided inside the slab, not inside the rib. The second flat surface, which serves as the junction surface of the vertical p-n junction, lies across the slab and the vicinity of the side surface of the rib.

Accordingly, it is inevitable that the first flat surface provided in the slab and a portion of the second flat surface, which serves as the junction surface of the p-n junction, are in a region having a very low optical density. This is because a width-direction optical density of light that is guided in the core is the highest at a center of the rib, gradually decreases in a direction away from the center of the rib, and further decreases in the slab, which is outside the rib.

As described above, the semiconductor optical waveguide illustrated in FIG. 2 of Patent Literature 2 has an increased total area of the junction surface due to the crank shape of the cross section of the junction surface of the p-n junction provided in the rib, but the increase in total area is not used efficiently for the improvement of modulation efficiency.

As described above, in each of the semiconductor optical waveguides illustrated in FIGS. 1 and 2 of Patent Literature 1, both modulation efficiency and high frequency characteristics are secured but the modulation efficiency leaves room for improvement.

The present invention is accomplished in view of the above problem. An object of the present invention is to (i) secure both modulation efficiency and high frequency characteristics in a semiconductor optical waveguide which includes a core having a p-type semiconductor region and an n-type semiconductor region and (ii) achieve further improvement of the modulation efficiency.

### Solution to Problem

In order to attain the object, a semiconductor optical waveguide of the present invention includes a core which is a rib-slab type core including a rib and a pair of slabs, the core being divided, by a boundary surface included in the rib, into a p-type semiconductor region made of a p-type semiconductor and an n-type semiconductor region made of an n-type semiconductor, the boundary surface being constituted by (i) a first flat surface which serves as a junction surface of a first lateral p-n junction, wherein an upper end of the first flat surface reaches an upper surface of the rib, (ii) a second flat surface which serves as a junction surface of a vertical p-n junction, wherein a left end of the second flat surface is connected to a lower end of the first flat surface, and (iii) a third flat surface which serves as a junction surface of a second lateral p-n junction, wherein an upper end of the third flat surface is connected to a right end of the second flat surface and a lower end of the third flat surface reaches a lower surface of the rib.

As described above, the boundary surface (a junction surface of a p-n junction) between the p-type semiconductor region and the n-type semiconductor region has a crank-shape constituted by the first flat surface, the second flat surface, and the third flat surface, all of which are provided inside the rib.

According to this configuration, a depletion layer formed near the junction surface of the p-n junction can be in a region closer to a center of the rib along the width of the rib, i.e., a region having a higher optical density, as compared with (i) a configuration illustrated in FIG. 1 of Patent Literature 2 in which the p-n junction has an L-shaped junction surface and (ii) a configuration illustrated in FIG. 2 of Patent Literature 2 in which the p-n junction has a crank-shaped junction surface.

This allows providing a semiconductor optical waveguide which has excellent high frequency characteristics like the configurations illustrated in FIGS. 1 and 2 of Patent Literature 2 and also has modulation efficiency better than those obtained with the configurations illustrated in FIGS. 1 and 2 of Patent Literature 2.

### Advantageous Effects of Invention

The present invention makes it possible to (i) secure both modulation efficiency and high frequency characteristics in a semiconductor optical waveguide which includes a core having a p-type semiconductor region and an n-type semiconductor region and (ii) achieve further improvement of the modulation efficiency.

### BRIEF DESCRIPTION OF DRAWINGS

(a) of FIG. 1 is a perspective view illustrating a configuration of a semiconductor optical waveguide in accordance with Embodiment 1, and (b) of FIG. 1 is a perspective view illustrating a configuration of a core included in the semiconductor optical waveguide.

(a) of FIG. 2 is a cross-sectional view illustrating a configuration of the semiconductor optical waveguide, and (b) of FIG. 2 is a cross-sectional view illustrating a configuration of the core included in the semiconductor optical waveguide.

(a) of FIG. 3 is a cross-sectional view illustrating a configuration of a core included in Modified Example 1 of the semiconductor optical waveguide in accordance with Embodiment 1, (b) of FIG. 3 is a cross-sectional view illustrating a configuration of a core included in Modified Example 2 of the semiconductor optical waveguide in accordance with Embodiment 1, and (c) of FIG. 3 is a cross-sectional view illustrating a configuration of a core included in Modified Example 3 of the semiconductor optical waveguide in accordance with Embodiment 1.

(a) of FIG. 4 is a graph showing a result of simulation of how an amount of change in phase of a semiconductor optical waveguide in accordance with each of Examples 1 and 2 of the present invention depends on a reverse bias voltage, and (b) of FIG. 4 is a graph showing a result of a simulation of how an attenuation constant of the semiconductor optical waveguide depends on an operating frequency.

(a) of FIG. 5 is a graph showing a result of simulation of a half wavelength voltage Vpi in a case where Wᵥₑᵣ₂ is caused to change in a range of not smaller than 80 nm but not greater than 200 nm in a semiconductor optical waveguide in accordance with Example Group 3 of the present invention, and (b) of FIG. 5 is a graph showing a result of simulation of a 3 dB bandwidth of the semiconductor optical waveguide in accordance with Example Group 3.

FIG. 6 is a graph showing an amount of change in phase observed in a case where a hole density in a p-type semiconductor region 12a is caused to change in a range of not less than 30% but not more than 130% relative to an electron density in an n-type semiconductor region in a semiconductor optical waveguide in accordance with Example 4 of the present invention.

FIG. 7 is a perspective view illustrating a configuration of a semiconductor optical modulator in accordance with Embodiment 2 of the present invention.

FIG. 8 is a cross-sectional view illustrating a configuration of a conventional semiconductor optical waveguide.

### DESCRIPTION OF EMBODIMENTS

A semiconductor optical waveguide in accordance with the present invention is a semiconductor optical waveguide which includes a rib-slab type core. The core is divided by a boundary surface included in the rib into a p-type semiconductor region made of a p-type semiconductor and an n-type semiconductor region made of an n-type semiconductor. The boundary surface is constituted by (i) a first flat surface which serves as a junction surface of a lateral p-n junction, wherein an upper end of the first flat surface reaches an upper surface of the rib, (ii) a second flat surface which serves as a junction surface of a vertical p-n junction, wherein a left end of the second flat surface is connected to a lower end of the first flat surface, and (iii) a third flat surface which serves as a junction surface of another lateral p-n junction, wherein an upper end of the third flat surface is connected to a right end of the second flat surface and a lower end of the third flat surface reaches a lower surface of the rib.

As such, the following description will discuss, as Embodiment 1 of the present invention, a semiconductor optical waveguide including a core which is what is called a rib-slab type core and includes a rib and a pair of slabs that are connected to respective both sides of the rib so as to sandwich the rib, and in which the rib is divided into a p-type semiconductor region and an n-type semiconductor region by a boundary surface included in the rib.

Further, a semiconductor optical modulator in accordance with the present invention is a Mach-Zehnder semiconductor optical modulator including arm sections, at least one of which is provided with an optical modulation section. The semiconductor optical modulator includes, as the optical modulation section, a semiconductor optical waveguide in accordance with one aspect of the present invention.

As such, the following description will discuss, as Embodiment 2 of the present invention, a Mach-Zehnder semiconductor optical modulator including arm sections, one of which is provided with the semiconductor optical waveguide in accordance with Embodiment 1 as a first semiconductor optical waveguide and the other of which is provided with the semiconductor optical waveguide in accordance with Embodiment 1 as a second semiconductor optical waveguide.

### Embodiment 1

A semiconductor optical waveguide 10 in accordance with Embodiment 1 of the present invention is described with reference to FIGS. 1 and 2. (a) of FIG. 1 is a perspective view illustrating a configuration of the semiconductor optical waveguide 10. (b) of FIG. 1 is a perspective view illustrating a configuration of a core 11 included in the semiconductor optical waveguide 10. (a) of FIG. 2 is a partial cross-sectional view of a part of a cross section taken along a line A-A′ in (a) of FIG. 1 and illustrating a configuration of the semiconductor optical waveguide 10. (b) of FIG. 2 is a partial cross-sectional view of a part of the cross section taken along the line A-A′ in (a) of FIG. 1 and illustrating a configuration of the core 11 included in the semiconductor optical waveguide 10. The cross section taken along the line A-A′ in (a) of FIG. 1 is a cross section (x-z plane) that is perpendicular to a direction (y direction) in which light is guided in a rib 12.

(Configuration of Semiconductor Optical Waveguide 10)

As illustrated in (a) of FIG. 1, the semiconductor optical waveguide 10 includes the core 11, a clad 19, a first electrode 15, a first signal line 16, a second electrode 17, and a second signal line 18. The clad 19 is constituted by a lower clad 19a and an upper clad 19b. The core 11 is provided on an upper surface of the lower clad 19a. The upper clad 19b is provided on the lower clad 19a and the core 11 so as to surround the core 11.

The core 11 is made of a material having a refractive index higher than that of a material of each of the lower clad 19a and the upper clad 19b. The material of the core 11 is, for example, a semiconductor typified by silicon, and the material of each of the lower clad 19a and the upper clad 19b is, for example, an insulator typified by silica. The lower clad 19a and the upper clad 19 may be made of the same material, or may be made of respective different materials.

The clad 19 may be configured such that the upper clad 19b is omitted. In this case, air surrounding the core 11 serves as an air clad.

Note that a coordinate system of (a) of FIG. 1 is defined as follows: (1) The y-axis is an axis that is parallel to a direction in which the rib 12 illustrated in (b) of FIG. 1 extends. The positive direction of the y-axis is defined as a direction from a front side to a back side of the drawing sheet of (a) of FIG. 1. (2) The z-axis is an axis that is parallel to a direction in which the thickness of the rib 12 illustrated in (b) of FIG. 1 extends. The positive direction of the z-axis is defined as a direction from the lower clad 19a to the upper clad 19b. (3) The x-axis is an axis that is parallel to a direction in which the width of the rib 12 illustrated in (b) of FIG. 1 extends. A direction of the x-axis is set such that the x-axis, the y-axis, and the z-axis constitute a right-handed coordinate system.

As illustrated in (b) of FIG. 1, the core 11 includes the rib 12, a first slab 13, and a second slab 14. A lower surface of the core 11 is a single flat surface constituted by surfaces, in flush with one another, of the rib 12, the first slab 13, and the second slab 14. The first slab 13 and the second slab 14 are equal in height along the z-axis, and the height of each of the first slab 13 and the second slab 14 is greater than a height of the rib 12 along the z-axis. That is, the core 11 is a rib-slab type core.

(Rib 12)

The rib 12 is divided by a boundary surface 12S into a p-type semiconductor region 12a and an n-type semiconductor region 12b. The p-type semiconductor region is made of a p-type semiconductor in which a semiconductor is doped with a p-type dopant. The n-type semiconductor region is made of an n-type semiconductor in which a semiconductor is doped with an n-type dopant. That is, the boundary surface 12S is a junction surface of a p-n junction 12J formed by joining the p-type semiconductor region 12a and the n-type semiconductor region 12b to each other. In the following description, the boundary surface 12S is also referred to as “junction surface 12S of the p-n junction 12J.” A concentration of each of the p-type dopant and the n-type dopant is not particularly limited, but may be 7×10⁻¹⁷ [cm⁻³], for example.

As illustrated in (a) of FIG. 2, the rib 12 is a region sandwiched between an upper surface 12us and a lower surface 12bs. The upper surface 12us is a surface constituted by a part of the p-type semiconductor region 12a which part is located at a highest point along the z-axis and a part of the n-type semiconductor region 12b which part is located at a highest point along the z-axis. The lower surface 12bs is a surface which is included in an area of the lower surface of the core 11 which area is obtained by reflecting the upper surface 12us onto the lower surface of the core 11. That is, a cross section of the rib 12 illustrated in (a) and (b) of FIG. 2 is in a shape of a rectangle, wherein the upper surface 12us, the lower surface 12bs, a right side surface 12rs, and a left side surface 121s of the rib 12 are positioned on four sides that constitute the rectangle. The boundary surface 12S is constituted by a first flat surface S1, a second flat surface S2, and a third flat surface S3.

The first flat surface S1 is a flat surface whose upper end reaches the upper surface 12us of the rib 12, the second flat surface S2 is a flat surface whose left end is connected to the first flat surface S1, and the third flat surface S3 is a flat surface whose upper end is connected to the second flat surface S2 and whose lower end reaches the lower surface 12bs of the rib 12. In other words, the second flat surface S2 is a flat surface which extends along the upper surface 12us and the lower surface 12bs of the rib 12, i.e., along the x-y plane, and each of the first flat surface S1 and the third flat surface S3 is a flat surface which extends along the right side surface 12rs and the left side surface 121s of the rib 12, i.e., along the y-z plane. Accordingly, an angle between the first flat surface S1 and the second flat surface S2 and an angle between the second flat surface S2 and the third flat surface S3 are each substantially 90°. Such a cross-sectional shape is referred to as “crank shape.”

Note that substantially 90°, which is the angle between the first flat surface S1 and the second flat surface S2 and the angle between the second flat surface S2 and the third flat surface S3, encompasses not only a designed angle of 90° but also a manufacturing error that is made during the manufacture of the semiconductor optical waveguide 10. This manufacturing error is assumed to be made in a manufacturing process for creating the p-type semiconductor region 12a and the n-type semiconductor region 12b inside the rib 12. For example, in a case where the p-type semiconductor region 12a and the n-type semiconductor region 12b are created by ion injection to silicon, a manufacturing error of ±5° is assumed with respect to the designed angle of 90°.

The first flat surface S1 divides an upper region of the rib 12 into the p-type semiconductor region 12a, which is a region on a left side and the n-type semiconductor region 12b, which is a region on a right side. That is, the p-type semiconductor region 12a and the n-type semiconductor region 12b are arranged side by side in a lateral direction (the x-axis direction) so as to be in contact with each other via the first flat surface S1 serving as a boundary. Accordingly, the first flat surface S1 serves as a junction surface of a first p-n junction J1, which is a lateral p-n junction.

The second flat surface S2 divides a central region of the rib 12 into the p-type semiconductor region 12a, which is a lower region, and the n-type semiconductor region 12b, which is an upper region. The central region is a region of the rib 12 which region is sandwiched between a plane including the first flat surface S1 and another plane including the third flat surface S3. That is, the p-type semiconductor region 12a and the n-type semiconductor region 12b are arranged side by side in a longitudinal direction (the z-axis direction) so as to be in contact with each other via the second flat surface S2 serving as a boundary. Accordingly, the second flat surface S2 serves as a junction surface of a second p-n junction J2, which is a vertical p-n junction.

The third flat surface S3 divides a lower region of the rib 12 into the p-type semiconductor region 12a, which is the region on the left side, and the n-type semiconductor region 12b, which is the region on the right side. That is, the p-type semiconductor region 12a and the n-type semiconductor region 12b are arranged side by side in a lateral direction (the x-axis direction) so as to be in contact with each other via the third flat surface S3 serving as a boundary. Accordingly, the third flat surface S3 serves as a junction surface of the third p-n junction J3, which is a lateral p-n junction.

As described above, the p-n junction 12J provided in a region near the boundary surface 12S is a crank-shaped p-n junction constituted by the first p-n junction J1, the second p-n junction J2, and the third p-n junction J3.

According to this configuration, a depletion layer formed near the junction surface of the first p-n junction J1 can be in a region closer to a center of the rib 12 along the width of the rib 12, i.e., a region having a higher optical density, as compared with (i) a configuration illustrated in FIG. 1 of Patent Literature 2 in which the p-n junction has a junction surface whose cross section is L-shaped and (ii) a configuration illustrated in FIG. 2 of Patent Literature 2 in which the p-n junction has a junction surface whose cross section is crank-shaped.

This allows the semiconductor optical waveguide 10 to have excellent high frequency characteristics like the configurations illustrated in FIGS. 1 and 2 of Patent Literature 2 and also to have modulation efficiency better than those obtained with the configurations illustrated in FIGS. 1 and 2 of Patent Literature 2.

As illustrated in (b) of FIG. 2, the core 11 is constituted such that the rib 12 has a thickness tᵣ that is greater than a thickness tₛ of each of the first slab 13 and the second slab 14. In the rib 12, a gap between the lower surface 12bs of the rib 12 and the second flat surface S2 is defined as a thickness tₚ of the p-type semiconductor region 12a, and a gap between the upper surface 12us of the rib 12 and the second flat surface S2 is defined as a thickness tₙ of the n-type semiconductor region 12b. That is, tᵣ=tₚ+tₙ. A gap between the right side surface 12rs of the rib 12 and the third flat surface S3 is defined as a width Wᵥₑᵣ₁, and a gap between the left side surface 121s of the rib 12 and the first flat surface S1 is defined as a width Wᵥₑᵣ₂.

In the rib 12, the width Wᵥₑᵣ₂ is preferably not greater than 1.8 times the width tₙ.

In the rib 12, the width Wᵥₑᵣ₂ is preferably not smaller than 1.1 times the thickness tₙ but not greater than 1.8 times the thickness tₙ.

As illustrated in (b) of FIG. 2, Embodiment 1 employs a configuration in which the upper surface of each of the first slab 13 and the second slab 14 is provided in the same plane as the second flat surface S2. In this case, tₛ=tₚ. Note that the upper surface of each of the first slab 13 and the second slab 14 may be provided in a plane different from a plane in which the second flat surface S2 is provided. In this case, it is preferable that tₚ>tₙ, as described later as Modified Example 1.

Further, although Embodiment 1 employs a configuration in which the thickness tₛ of each of the first slab 13 and the second slab 14 is half the thickness tᵣ of the rib 12, a ratio of the thickness tᵣ to the thickness tₛ is not limited to 50%. The ratio of the thickness tᵣ to the thickness tₛ can be set appropriately so as to allow light guided in the rib 12 to be more confined inside the rib 12 (so as to further suppress leakage of the light out to the first slab 13 and the second slab 14).

(Asymmetrical Doping in p-Type Semiconductor Region and n-Type Semiconductor Region)

In a semiconductor optical waveguide in accordance with one aspect of the present invention, a ratio of a hole density in the p-type semiconductor region 12a to an electron density in the n-type semiconductor region 12b is preferably more than 35% but less than 100%. In the description below, a case in which the ratio of the hole density in the p-type semiconductor region 12a to the electron density in the n-type semiconductor region 12b is 100% is referred to as symmetrical doping, and a case in which the ratio of the hole density in the p-type semiconductor region to the electron density in the n-type semiconductor region is less than 100% is referred to as asymmetrical doping.

The present inventors employed asymmetrical doping and found that, in a case where the ratio of the hole density in the p-type semiconductor region 12a to the electron density in the n-type semiconductor region 12b is more than 35% but less than 100%, a greater phase shift amount is obtained as compared with a case where symmetrical doping is employed. That is, the above-described configuration enables further improvement of modulation efficiency.

(Materials of Core 11 and Clad 19)

In a case where a core 11 in which silicon, which is a base material, is doped with a p-type dopant and an n-type dopant is employed in the semiconductor optical waveguide 10 in accordance with Embodiment 2, the semiconductor optical waveguide 10 may be fabricated with use of, for example, an SOI (Silicon on Insulator) substrate.

In this case, a BOX layer (thermally-oxidized film layer) of the SOI substrate can be used as the lower clad 19a so that a Si layer that is formed on the BOX layer is patterned into the shape of the core 11. The p-type semiconductor region 12a, the n-type semiconductor region 12b, the first slab 13, and the second slab 14 included in the core 11 can each be realized by doping the Si layer on the BOX layer with a dopant.

Further, the upper clad 19b surrounding the core 11 can be formed by stacking, on the lower clad 19a and the core 11, an insulator (e.g. silica) having a refractive index lower than that of silicon.

Note that in a case where the semiconductor optical waveguide 10 is fabricated with use of the SOI substrate, a Si layer (not shown in FIGS. 1 and 2) is present in a layer below the lower clad 19a.

An existing process for fabricating a semiconductor optical waveguide is applicable to these processes for fabricating the semiconductor optical waveguide 10. Accordingly, the semiconductor optical waveguide 10 can be fabricated at approximately the same cost as that for fabricating a conventional semiconductor optical waveguide. In other words, the semiconductor optical waveguide 10 can be fabricated to have further improved modulation efficiency, without an increase in fabrication cost.

Note that the semiconductor used as the base material of the core 11 is not limited to silicon, and may be, for example, indium phosphide. That is, it is possible to employ a configuration in which the p-type semiconductor region 12a is made of a semiconductor in which indium phosphide is doped with a p-type dopant, and the n-type semiconductor region 12b is made of a semiconductor in which indium phosphide is doped with an n-type dopant.

In this case, it is preferable that the lower clad 19a be made of a semiconductor in which indium phosphide is doped with a dopant, and the upper clad 19b be made of any one of (i) a semiconductor in which indium phosphide is doped with a dopant, (ii) silica, and (iii) air.

Further, an intrinsic semiconductor region made of an intrinsic semiconductor may be further provided on the upper surface of the rib 12 of the core 11.

(First Slab 13 and Second Slab 14)

Like the p-type semiconductor region 12a, the first slab 13 connected to the p-type semiconductor region 12a is made of a p-type semiconductor. The hole density in the p-type semiconductor region 12a and the hole density in the first slab 13 may be equal to each other, or different from each other. In a case of employing a configuration in which the hole density in the p-type semiconductor region 12a and the hole density in the first slab 13 are different from each other, the hole density in the first slab 13 is preferably higher than the hole density in the p-type semiconductor region 12a.

Like the n-type semiconductor region 12b, the second slab 14 connected to the n-type semiconductor region 12b is made of an n-type semiconductor. The electron density in the n-type semiconductor region 12b and the electron density in the second slab 14 may be equal to each other, or different from each other. In a case of employing a configuration in which the electron density in the n-type semiconductor region 12b and the electron density in the second slab 14 are different from each other, the electron density in the second slab 14 is preferably higher than the electron density in the n-type semiconductor region 12b.

(Electrodes 15 and 17 and Signal Lines 16 and 18)

The first electrode 15 is an electrode which is made of an electric conductor and provided so as to extend from the upper surface of the first slab 13 to an upper surface of the upper clad 19b and lie along the y-axis direction. The first electrode 15 is electrically connected with the first slab 13. The first signal line 16 is an electrode which is made of an electric conductor and provided on an upper surface of the first electrode 15 and the upper surface of the upper clad 19b. The first signal line 16 is electrically connected with the first electrode 15. That is, the first signal line 16 and the p-type semiconductor region 12a are electrically connected with each other via the first slab 13 and the first electrode 15.

The second electrode 17 is an electrode which is made of an electric conductor and provided so as to extend from the upper surface of the second slab 14 to the upper surface of the upper clad 19b and lie along the y-axis direction. The second electrode 17 is electrically connected with the second slab 14. The second signal line 18 is an electrode which is made of an electric conductor and provided on an upper surface of the second electrode 17 and the upper surface of the upper clad 19b. The second signal line 18 is electrically connected with the second electrode 17. That is, the second signal line 18 and the n-type semiconductor region 12b are electrically connected with each other via the second slab 14 and the second electrode 17.

With use of the first signal line 16 and the second signal line 18 thus configured, a modulation voltage can be applied to the p-type semiconductor region 12a and the n-type semiconductor region 12b of the rib 12. That is, the semiconductor optical waveguide 10 can serve as a phase modulator for modulating a phase of light guided in the rib 12 of the core 11.

Note that the modulation voltage applied to the rib 12 has a polarity that is in a reverse bias direction with respect to the p-n junction 12J inside the rib 12.

Note that the first electrode 15 and the second electrode 17 are preferably constituted by a pair of traveling-wave electrodes. That is, it is preferable that the first electrode 15 and the second electrode 17 be a first traveling-wave electrode and a second traveling-wave electrode, respectively.

In a case where optical phase modulation is carried out with use of the semiconductor optical waveguide 10, the configuration above allows an increase in speed of the phase modulation operation.

### Modified Example 1

The following description will discuss, with reference to (a) of FIG. 3, Modified Example 1 of the semiconductor optical waveguide 10 in accordance with Embodiment 1. (a) of FIG. 3 is a cross-sectional view illustrating a configuration of a core 11 included in a semiconductor optical waveguide 10 in accordance with Modified Example 1.

The semiconductor optical waveguide 10 in accordance with Modified Example 1 is obtained by configuring the semiconductor optical waveguide 10 (see (b) of FIG. 2) in accordance with Embodiment 1 such that the thickness tₚ of the p-type semiconductor region 12a is greater than the thickness tₙ of the n-type semiconductor region 12b.

Note that in the Description, a center of the rib 12 is defined as a position at which a plane obtained by equally dividing the rib 12 along a height (a width between the lower surface 12bs and the upper surface 12us) of the rib 12 and another plane obtained by equally dividing the rib 12 along a width (a width between the right side surface 12rs and the left side surface 121s) of the rib 12 intersect with each other. That is, the center of the rib 12 refers to a point at which two diagonal lines of the rectangle constituted by the upper surface 12us, the lower surface 12bs, the right side surface 12rs, and the left side surface 121s intersect with each other. Note that in a perspective view such as the perspective view of (a) of FIG. 3, the center of the rib 12 extends along the y-axis. Further, it is preferable that, as illustrated in (a) of FIG. 3, the center (a center C in (a) of FIG. 3) and the second flat surface S2 are positioned at a distance from each other and the center C be contained in the p-type semiconductor region 12b.

Here, when amounts of change in phase of holes, which are carriers in the p-type semiconductor region, and amounts of change in phase of electrons, which are carriers in the n-type semiconductor region 12b, are compared per carrier, an amount of change in phase of a hole is greater than an amount of change in phase of an electron. Further, light guided in the rib-slab type core has an optical density which, along the height of the rib 12, becomes the highest at the center C of the rib 12 or at a portion of the rib 12 which portion is below the center C.

According to the semiconductor optical waveguide 10 in accordance with Modified Example 1, the center C of the rib or the portion of the rib below the center C, where the optical density becomes the highest along the height of the rib, is contained in the p-type semiconductor region 12a in which the amount of change in phase is greater than that in the n-type semiconductor region 12b. This allows a region having a high optical density to be used more effectively as compared with a case (1) in which the center C is positioned on the second flat surface S2 and a case (2) in which the center C is contained in the n-type semiconductor region 12b. Accordingly, further improvement of modulation efficiency is achieved.

Further, in a case of employing a configuration in which the p-type semiconductor region 12a and the n-type semiconductor region 12b are symmetrically doped, it is preferable that a distance between the center C and the second flat surface S2 be not smaller than 50% but not greater than 100% of a thickness of a depletion layer that is formed by a built-in potential.

As the number of carriers changes according to a modulation voltage by a greater amount, an amount of optical phase shift increases. At a p-n junction, an amount of change in the number of carriers according to the modulation voltage is the greatest at a position near an outer side of a depletion layer that is formed by a built-in potential.

According to this configuration, the center C of the rib 12 is located at a position near an outer side of the depletion layer, at which position a carrier density changes by a large amount. This allows a region having a highest optical density in the rib 12 and a region having a largest amount of change in the number of carriers to overlap with each other. Accordingly, further improvement of modulation efficiency is achieved.

On the other hand, in a case of employing a configuration in which the p-type semiconductor region 12a and the n-type semiconductor region 12b are asymmetrically doped, it is preferable that the distance between the center C and the second flat surface S2 be not smaller than 50% but not greater than 200% of a thickness of a depletion layer that is formed by a built-in potential. In the case of employing the configuration in which the p-type semiconductor region 12a and the n-type semiconductor region 12b are asymmetrically doped, the depletion layer extends from the second flat surface S2 toward an inside of the p-type semiconductor region 12a, as compared with the case of employing the configuration in which the p-type semiconductor region 12a and the n-type semiconductor region 12b are symmetrically doped.

As such, according to the above configuration, the center C of the rib 12 is located at a position near an outer side of the depletion layer, at which position a carrier density changes by a large amount. This enables further improvement of modulation efficiency.

### Modified Example 2

Modified Example 2 of the semiconductor optical waveguide 10 in accordance with Embodiment 1 is described with reference to (b) of FIG. 3. (b) of FIG. 3 is a cross-sectional view illustrating a core 11 included in a semiconductor optical waveguide 10 in accordance with Modified Example 2.

The semiconductor optical waveguide 10 in accordance with Modified Example 2 is obtained by configuring the semiconductor optical waveguide 10 in accordance with Embodiment 1 (see (b) of FIG. 2) such that (1) the thickness tₚ is greater than the thickness tₙ and (2) the width Wᵥₑᵣ₂ is smaller than the thickness tₙ. In other words, the semiconductor optical waveguide 10 in accordance with Modified Example 2 is obtained by configuring the semiconductor optical waveguide 10 in accordance with Modified Example 1 such that the width Wᵥₑᵣ₂ is smaller than the thickness tₙ.

According to this configuration, in a case where a p-n junction 12J having a junction surface 12S with a crank shape is provided inside a rib 12, the crank-shaped junction surface 12S can have an increased total area. This increases a capacitance of the p-n junction 12J and, accordingly, enables an increase in amount of change in phase. That is, the configuration enables improvement of modulation efficiency.

Note that although the increase in capacitance of the p-n junction 12J enables the improvement of modulation efficiency, the increase in capacitance also causes high frequency components to attenuate more, so that high frequency characteristics are deteriorated. The deterioration in high frequency characteristics caused by the increase in capacitance will be described later with reference to (b) of FIG. 5.

Note that in a case where the width Wᵥₑᵣ₂ is reduced too much in the semiconductor optical waveguide 10 in accordance with Modified Example 2 and, accordingly, a p-type semiconductor region of a first p-n junction J1 is reduced too much, it becomes difficult to secure sufficient amount of change in the number of carriers in the p-type semiconductor region. Therefore, even in a case where modulation efficiency and high frequency characteristics are both secured and the modulation efficiency is further improved, it is preferable that the width Wᵥₑᵣ₂ be not smaller than 0.8 times the thickness tₙ, in consideration of a possibility that the amount of change in the number of carriers is saturated (see (a) of FIG. 5).

### Modified Example 3

Modified Example 3 of the semiconductor optical waveguide 10 in accordance with Embodiment 1 is described with reference to (c) of FIG. 3. (c) of FIG. 3 is a cross-sectional view illustrating a configuration of a core 11 included in a semiconductor optical waveguide 10 in accordance with Modified Example 3.

The semiconductor optical waveguide 10 in accordance with Modified Example 3 is obtained by configuring the semiconductor optical waveguide 10 in accordance with Embodiment 1 (see (b) of FIG. 2) such that (1) the thickness tₚ is greater than the thickness tₙ and (2) the width Wᵥₑᵣ₂ is greater than the thickness tₙ. In other words, the semiconductor optical waveguide 10 in accordance with Modified Example 3 is obtained by configuring the semiconductor optical waveguide 10 in accordance with Modified Example 1 such that the width Wᵥₑᵣ₂ is greater than the thickness tₙ.

According to this configuration, a junction surface 12S of a p-n junction 12J has a reduced total area as compared with the semiconductor optical waveguide 10 in accordance with Modified Example 1. The reduction in total area of the junction surface 12S means a reduction in volume of a depletion layer that is formed near the junction surface 12S. This results in a negative effect that the number of carriers contributing to phase modulation is decreased. On the other hand, increasing the width Wᵥₑᵣ₂ allows the first flat surface S1 to be closer to a center C of a rib 12, i.e., to be provided in a region having a higher optical density along a width of the rib 12. This brings about a positive effect that the number of carriers contributing to phase modulation is increased.

As described later with reference to (a) of FIG. 5, in a case where the width Wᵥₑᵣ₂ is gradually increased so as to be greater than the thickness tₙ, a half wavelength voltage Vpi (1) remains at the same level in a range of Wᵥₑᵣ₂ of not smaller than 0.8 times tₙ but not greater than 1.4 times tₙ, (2) begins to increase significantly in a range of Wᵥₑᵣ₂ of greater than 1.5 times tₙ, and (3) surpasses a half wavelength voltage Vpi of a semiconductor optical waveguide having an L-shaped junction surface in a range of Wᵥₑᵣ₂ of greater than 1.8 times tₙ.

As such, in a case where a distance between the left side surface 121s of the rib 12 and the first flat surface S1 is not greater than 1.8 times a distance between the upper surface 12us of the rib 12 and the second flat surface S2, the positive effect surpasses the negative effect, so that the half wavelength voltage Vpi can be suppressed as compared with a case in which a boundary surface between a p-type semiconductor region and an n-type semiconductor region is L-shaped (a configuration in which a first flat surface extends from a left end of a second flat surface to a left side surface of a rib). That is, improvement of modulation efficiency is achieved.

Further, the reduction in total area of the junction surface 12S deteriorates modulation efficiency but allows suppression of a capacitance of the p-n junction 12J. Therefore, the reduction in total area of the junction surface 12S brings about an advantageous effect that high frequency characteristics are improved. As described later with reference to (b) of FIG. 5, the high frequency characteristics of the semiconductor optical waveguide in accordance with Modified Example 3 surpass high frequency characteristics of a semiconductor optical waveguide having an L-shaped junction surface in a range of the width Wᵥₑᵣ₂ of Wᵥₑᵣ₂≧1.1×tₙ.

Therefore, it is preferable that the semiconductor optical waveguide 10 be configured such that the width Wᵥₑᵣ₂ is not smaller than 1.1 times the thickness tₙ but not greater than 1.8 times the thickness tₙ. This configuration makes it possible to secure both modulation efficiency and high frequency characteristics at higher levels.

### Examples 1 and 2

A semiconductor optical waveguide 10 in accordance with each of Examples 1 and 2 of the present invention is described with reference to FIG. 4.

(a) of FIG. 4 is a graph showing a result of simulation of how an amount of change in phase of a semiconductor optical waveguide 10 in accordance with each of Examples 1 and 2 depends on a reverse bias voltage. The amount of change in phase is a physical quantity corresponding to modulation efficiency, and a larger amount of change in phase means higher modulation efficiency.

(b) of FIG. 4 is a graph showing how an attenuation constant of the semiconductor optical waveguide 10 in accordance with each of Examples 1 and 2 depends on an operating frequency. The attenuation constant is a physical quantity corresponding to high frequency characteristics, and a lower attenuation constant means better high frequency characteristics.

Note that (a) of FIG. 4 also shows a result of simulation of how an amount of change in phase of a semiconductor optical waveguide 110, which is Comparative Example of the present invention, depends on a reverse bias voltage, and (b) of FIG. 4 also shows how an attenuation constant of the semiconductor optical waveguide 110 depends on an operating frequency.

The semiconductor optical waveguide 10 of each of Examples 1 and 2 is assumed to (1) employ the configuration of Modified Example 1 illustrated in (a) of FIG. 3 and (2) be fabricated with use of an SOI substrate in which a silicon layer provided on a BOX layer has a thickness of 220 nm. Accordingly, both of the semiconductor optical waveguides 10 of respective Examples 1 and 2 employ the following configurations.
The p-type semiconductor region 12a is made of a p-type semiconductor in which silicon is doped with a p-type dopant.
The n-type semiconductor region 12b is made of an n-type semiconductor in which silicon is doped with an n-type dopant.
The first slab 13 is made of a p-type semiconductor in which silicon is doped with a p-type dopant.
The second slab 14 is made of an n-type semiconductor in which silicon is doped with an n-type dopant.
The doping concentration of each of the p-type dopant contained in the p-type semiconductor region 12a and the p-type dopant contained in the first slab 13 is 7×10⁻¹⁷ [cm⁻³].
The doping concentration of each of the n-type dopant contained in the n-type semiconductor region 12b and the n-type dopant contained in the second slab 14 is 7×10⁻¹⁷ [cm⁻³].
The lower clad 19a and the upper clad 19b are each made of silica.
The rib 12 has a width of 500 nm.
The rib 12 has a thickness tᵣ of 220 nm.
Each of the first slab 13 and the second slab 14 has a thickness tₛ of 100 nm.
The p-type semiconductor region 12a has a thickness tₚ of 120 nm.
The n-type semiconductor region 12n has a thickness tₙ of 100 nm.
The width Wᵥₑᵣ₁ is 100 nm.

In addition to the configurations above, the semiconductor optical waveguide 10 in accordance with Example 1 has a width Wᵥₑᵣ₂ of 100 nm and the semiconductor optical waveguide 10 in accordance with Example 2 has a width Wᵥₑᵣ₂ of 150 nm.

### Comparative Example

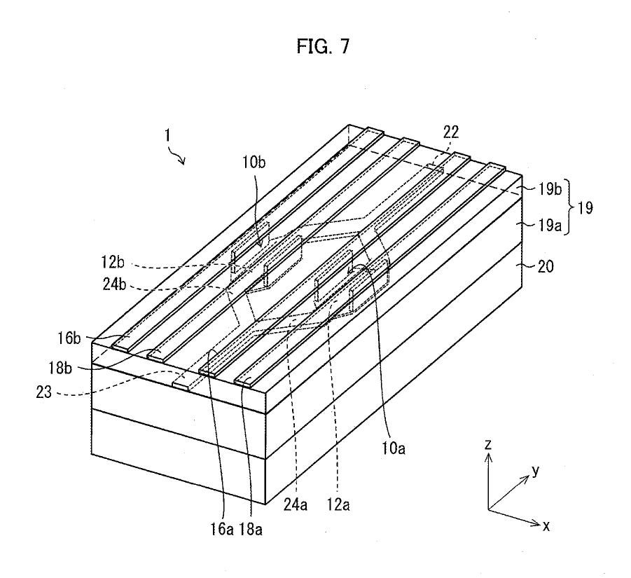

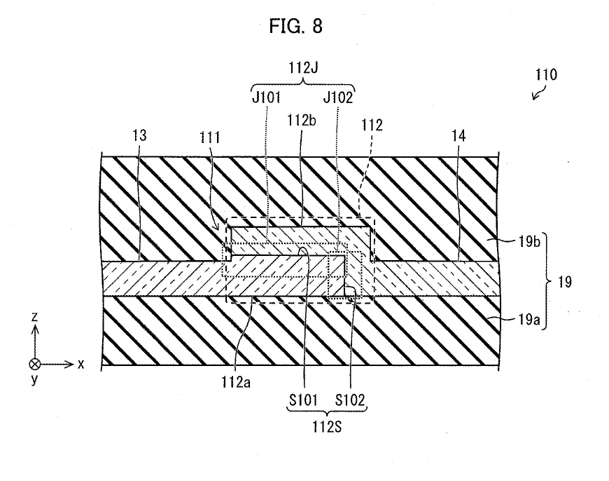

The following description will discuss, with reference to FIG. 8, the semiconductor optical waveguide 110 which is Comparative Example of the present invention. FIG. 8 is a cross-sectional view illustrating a configuration of the semiconductor optical waveguide 110 in accordance with Comparative Example. The semiconductor optical waveguide 110 differs from the semiconductor optical waveguide 10 in accordance with Example 1 in terms of a shape of a boundary surface 112S provided inside a rib 112.

The boundary surface 112S which divides the rib 112 into a p-type semiconductor region 112a and an n-type semiconductor region 112b is constituted by a first flat surface S101 and a second flat surface S102. The first flat surface S101 is a flat surface whose left end reaches a left side surface of the rib 112, and the second flat surface S102 is a flat surface whose upper end is connected to a right end of the first flat surface S101 and whose lower end reaches a lower surface of the rib 112. That is, the semiconductor optical waveguide 110 includes a p-n junction 112J in which the boundary surface 112S having an L-shape serves as a junction surface.

The semiconductor optical waveguide 110 differs from the semiconductor optical waveguide 10 in accordance with Example 1 in that while the semiconductor optical waveguide 10 in accordance with Example 1 is configured such that the first flat surface S1 connected to the left end of the second flat surface S2 reaches the upper surface 12us of the rib 12, the semiconductor optical waveguide 110 is configured such that the first flat surface S101 extends from the upper end of the second flat surface S102 to the left side surface of the rib 112.

(Modulation Efficiency)

With reference to (a) of FIG. 4, it was found that, in a range of a reverse bias voltage of not lower than 0 V but not higher than 6 V, each of the semiconductor optical waveguide 10 in accordance with Example 1 and the semiconductor optical waveguide 10 in accordance with Example 2 had a greater amount of change in phase as compared with the semiconductor optical waveguide 110.

This is because the first p-n junction J1 whose junction surface is the first flat surface S1 is provided in a region near the center C of the rib 12 due to the above-described configurations in which the first flat surface S1 reaches the upper surface 12us of the rib 12 and Wᵥₑᵣ₂ is set to 100 nm or 150 nm. According to these configurations, the depletion layer of the first p-n junction J1 overlaps with a region having a high optical density. This allows an amount of change in the number of carriers according to a modulation voltage to be effectively used for optical phase modulation.

Note that it was found that an amount of change in phase of the semiconductor optical waveguide 10 in accordance with Example 2 was at the same level as but slightly more than an amount of change in phase of the semiconductor optical waveguide 10 in accordance with Example 1.

This is considered to be because the positive effect (since a region having a high optical density can be used as the first p-n junction J1, an amount of change in phase increases) resulting from changing Wᵥₑᵣ₂ from 100 nm to 150 nm surpasses the negative effect (since the total area of the junction surface 12S of the p-n junction 12J is reduced, an amount of change in phase decreases).

(High Frequency Characteristics)

With reference to (b) of FIG. 4, it was found that, in an operating frequency band of not lower than 20 GHz but not higher than 50 GHz, the semiconductor optical waveguide 10 in accordance with Example 1 had an attenuation constant which was at the same level as but slightly greater than an attenuation constant of the semiconductor optical waveguide 110 in accordance with Comparative Example. On the other hand, it was found that, in an operating frequency band of not lower than 20 GHz but not higher than 50 GHz, the semiconductor optical waveguide 10 in accordance with Example 2 had an attenuation constant which was significantly smaller than the attenuation constant of the semiconductor optical waveguide 10 in accordance with Example 1 and the attenuation constant of the semiconductor optical waveguide 110 in accordance with Comparative Example.

The above difference observed between the semiconductor optical waveguide 10 in accordance with Example 1 and the semiconductor optical waveguide 10 in accordance with Example 2 is because the semiconductor optical waveguide 10 in accordance with Example 1 and the semiconductor optical waveguide 10 in accordance with Example 2 differ in total area of the boundary surface 12S due to a difference in position where the first flat surface S1 is provided. Due to a difference in width Wᵥₑᵣ₂ of 50 nm between the semiconductor optical waveguide 10 in accordance with Example 1 and the semiconductor optical waveguide 10 in accordance with Example 2, the boundary surface 12S of the semiconductor optical waveguide 10 in accordance with Example 2 has a total area smaller than that of the boundary surface 12S of the semiconductor optical waveguide 10 in accordance with Example 1. It is therefore assumed that the semiconductor optical waveguide 10 in accordance with Example 2 has a capacitance smaller than that of the semiconductor optical waveguide 10 in accordance with Example 1 and, accordingly, has an attenuation constant smaller than that of the semiconductor optical waveguide 10 in accordance with Example 1.

It was therefore found that the semiconductor optical waveguide 10 in accordance with Example 2 (Wᵥₑᵣ₂=150 nm) can secure both modulation efficiency and high frequency characteristics at higher levels than those of the semiconductor optical waveguide 10 in accordance with Example 1 (Wᵥₑᵣ₂=100 nm).

### Example Group 3

A semiconductor optical waveguide 10 in accordance with Example Group 3 of the present invention is described with reference to FIG. 5. The semiconductor optical waveguide 10 in accordance with Example Group 3 was examined as to how a total area of a junction surface 12S affects modulation efficiency and high frequency characteristics in accordance with a change in width Wᵥₑᵣ₂ causes.

(a) of FIG. 5 is a graph showing a result of simulation of how a half wavelength voltage Vpi of the semiconductor optical waveguide 10 in accordance with Example Group 3 depends on the width Wᵥₑᵣ₂. The half wavelength voltage Vpi is a physical quantity corresponding to modulation efficiency, and a smaller half wavelength voltage Vpi means higher modulation efficiency.

(b) of FIG. 5 is a graph showing a result of simulation of how a 3 dB bandwidth of the semiconductor optical waveguide 10 in accordance with Example Group 3 depends on the width Wᵥₑᵣ₂. The 3 dB bandwidth is a physical quantity corresponding to high frequency characteristics, and a wider 3 dB bandwidth means better high frequency characteristics.

Note that (a) of FIG. 5 also shows a result of simulation of a half wavelength voltage Vpi of the semiconductor optical waveguide 110, which is Comparative Example of the present invention, and (b) of FIG. 5 also shows a result of simulation of a 3 dB bandwidth of the semiconductor optical waveguide 110. In each of (a) and (b) of FIG. 5, a plot corresponding to Wᵥₑᵣ₂=0 nm indicates a result of simulation conducted with use of the semiconductor optical waveguide 110.

The semiconductor optical waveguide 10 in accordance with Example Group 3 employed similar configurations as those employed in the semiconductor optical waveguide 10 in accordance with Example 1, except that the width Wᵥₑᵣ₂ was caused to change in a range of not smaller than 80 nm but not greater than 200 nm.

(Modulation Efficiency)

As shown in (a) of FIG. 5, in a range of the width Wᵥₑᵣ₂ of not smaller than 80 nm but not greater than 140 nm, i.e., a range of the width Wᵥₑᵣ₂ of W not smaller than 0.8 times the thickness tₙ but not greater than 1.4 times the thickness tₙ, the half wavelength voltage Vpi of the semiconductor optical waveguide 10 was lower than the half wavelength voltage Vpi of the semiconductor optical waveguide 110 in accordance with Comparative Example.

In a range of the width Wᵥₑᵣ₂ of W greater than 150 nm, i.e., a range of the width Wᵥₑᵣ₂ of W greater than 1.5 times the thickness tₙ, the half wavelength voltage Vpi of the semiconductor optical waveguide 10 began to increase significantly.

In a range of the width Wᵥₑᵣ₂ of W greater than 180 nm, i.e., a range of the width Wᵥₑᵣ₂ of W greater than 1.8 times the thickness tₙ, the half wavelength voltage Vpi of the semiconductor optical waveguide 10 surpassed the half wavelength voltage Vpi of the semiconductor optical waveguide 110 in accordance with Comparative Example.

It was therefore found that in a range of the width Wᵥₑᵣ₂ of not smaller than 0.8 times the thickness tₙ but not greater than 1.8 times the thickness tₙ, the semiconductor optical waveguide 10 in accordance with Example Group 3 exhibits a modulation efficiency higher than that of the semiconductor optical waveguide 110 in accordance with Comparative Example.

(High Frequency Characteristics)

As shown in (b) of FIG. 5, in a range of the width Wᵥₑᵣ₂ of not smaller than 80 nm but not greater than 110 nm, i.e., a range of the width Wᵥₑᵣ₂ of not smaller than 0.8 times the thickness tₙ but not greater than 1.1 times the thickness tₙ, the 3 dB bandwidth of the semiconductor optical waveguide 10 was narrower than that of the semiconductor optical waveguide 110 in accordance with Comparative Example.

In a range of the width Wᵥₑᵣ₂ of not smaller than 110 nm but not greater than 200 nm, i.e., a range of the width Wᵥₑᵣ₂ of not smaller than 1.1 times the thickness tₙ but not greater than 2.0 times the thickness tₙ, the 3 dB bandwidth of the semiconductor optical waveguide 10 was wider than that of the semiconductor optical waveguide 110 in accordance with Comparative Example.

It was therefore found that in a range of the width W_{Ver2} was of smaller than 1.1 times the thickness tₙ but not greater than 2.0 times the thickness tₙ, the semiconductor optical waveguide 10 in accordance with Example Group 3 has high frequency characteristics better than those of the semiconductor optical waveguide 110 in accordance with Comparative Example.

Therefore, it was found that, in a region in which the width Wᵥₑᵣ₂ was not smaller than 1.1 times the thickness tₙ but not greater than 1.8 times the thickness tₙ, the semiconductor optical waveguide 10 in accordance with Example Group 3 can secure both modulation efficiency and high frequency characteristics and also achieve further improvement of modulation efficiency.

### Example 4

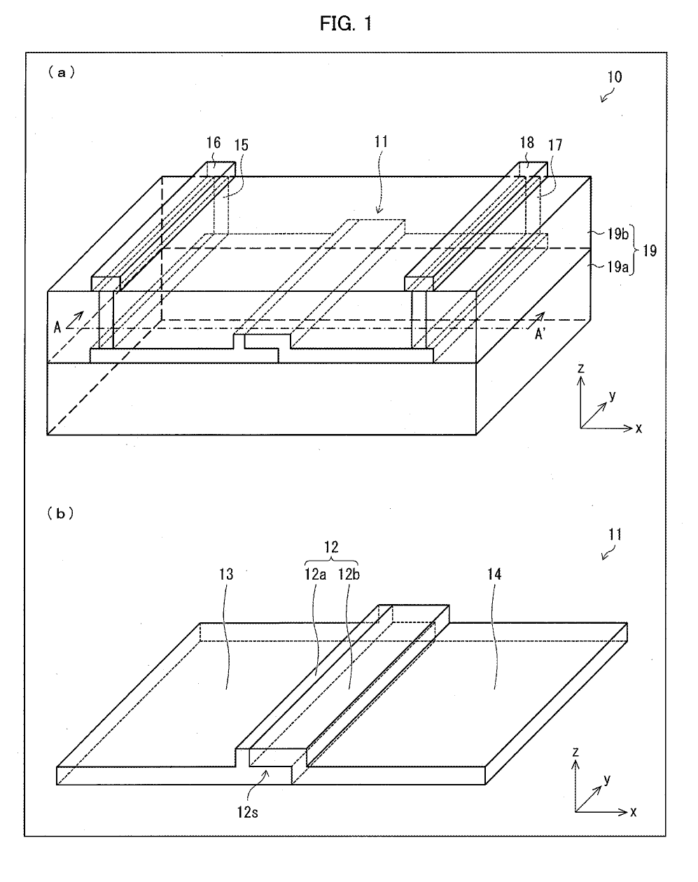

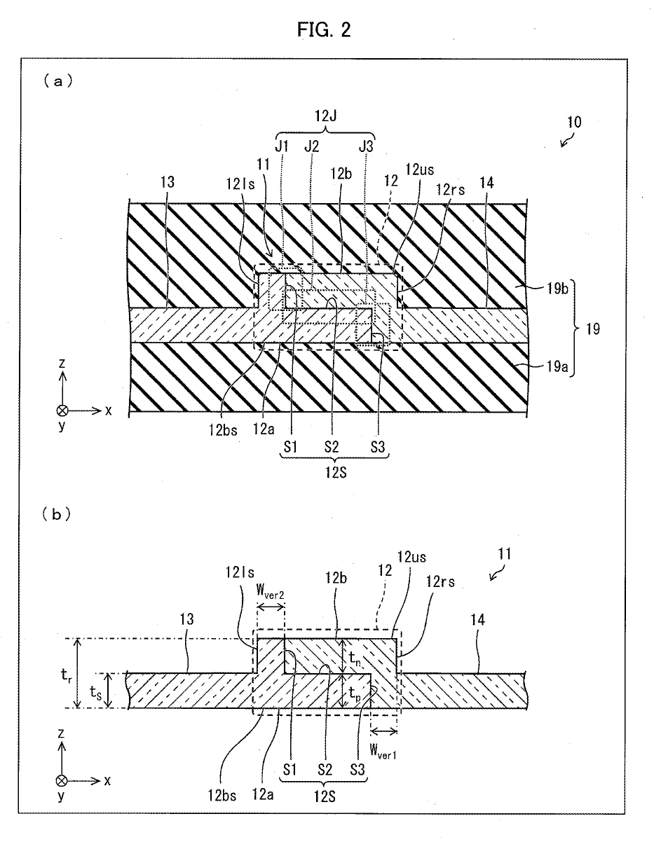

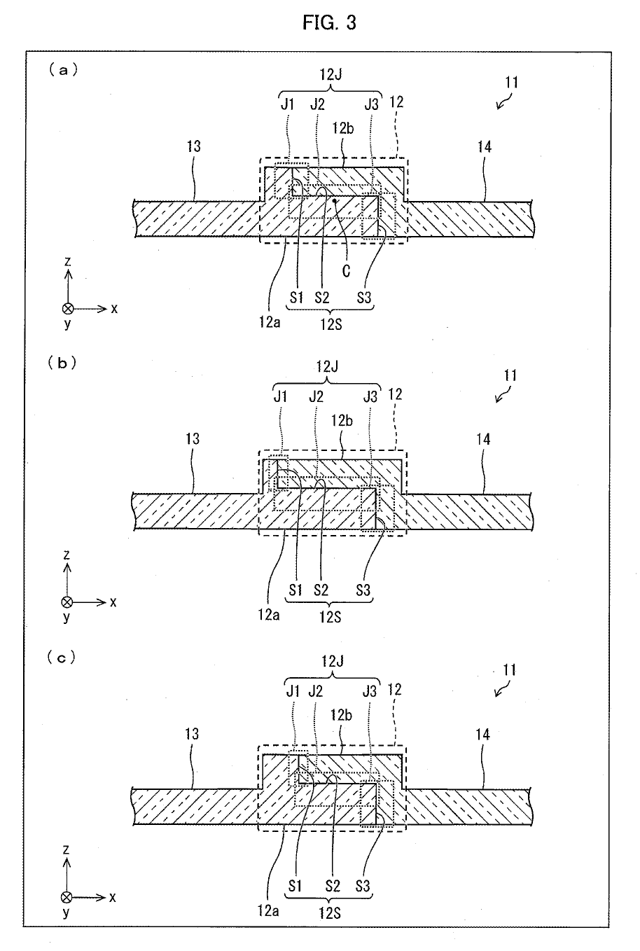

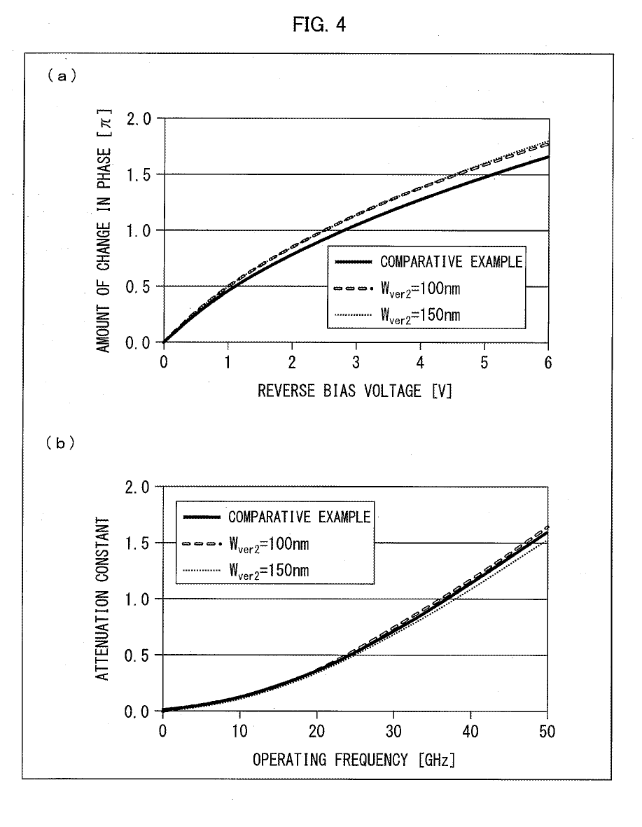

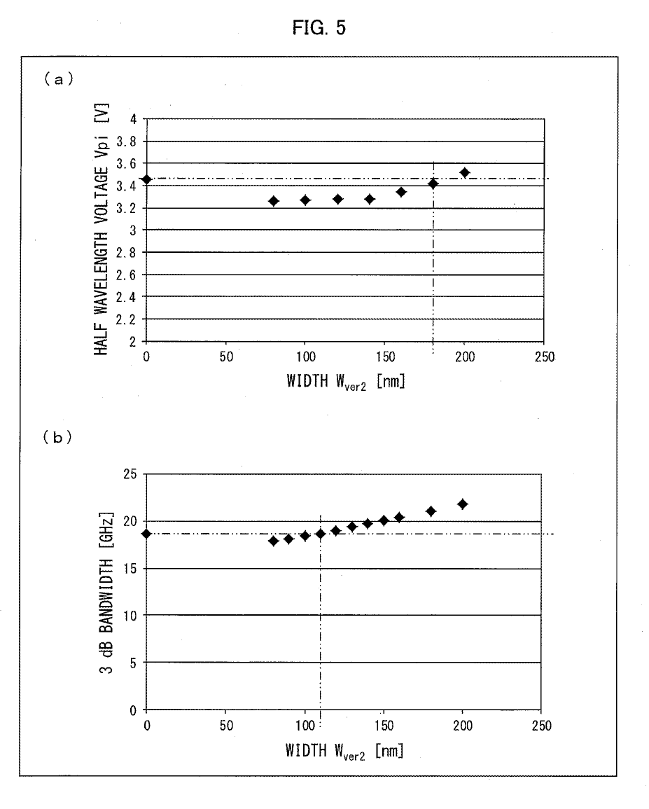

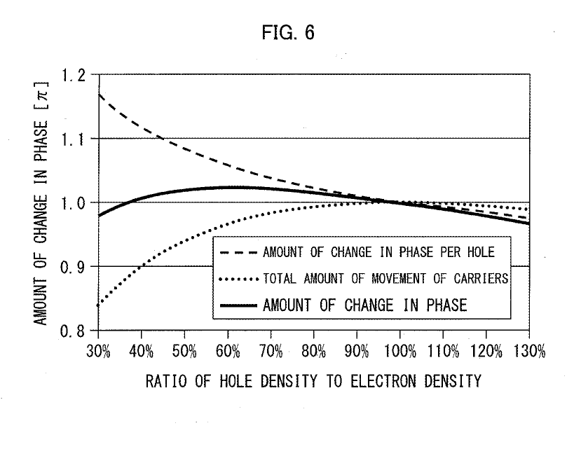

A semiconductor optical waveguide 10 in accordance with Example 4 of the present invention is described with reference to FIG. 6. FIG. 6 is a graph showing an amount of change in phase observed in a case where a hole density in a p-type semiconductor region 12a is caused to change in a range of not less than 30% but not more than 130% relative to an electron density in an n-type semiconductor region 12b in the semiconductor optical waveguide 10 in accordance with Example 4.

In a case where a ratio of the hole density to the electron density is 100%, the p-type semiconductor region 12a has a doping level equal to that of the n-type semiconductor region 12b. Such a doping is referred to as symmetrical doping. In a case where the ratio of the hole density to the electron density is 50%, the p-type semiconductor region 12a has a doping level that is half a doping level of the n-type semiconductor region 12b. Such a doping is referred to as asymmetrical doping.

In FIG. 6, a broken line indicates an amount of change in phase per hole, a dotted line indicates a total amount of movement of carriers in a case where a predetermined modulation voltage was applied, and a solid line indicates a total amount of change in phase. The total amount of change in phase is determined by multiplying the amount of change in phase per hole by the total amount of movement of the carriers in the case where the predetermined modulation voltage was applied.

As shown in FIG. 6, the amount of change in phase per hole monotonically decreased as the ratio of the hole density to the electron density increased. The total amount of movement of carriers in the case where the predetermined modulation voltage was applied monotonically increased in a range of the ratio of the hole density to the electron density of not less than 30% but not more than 100%, and monotonically decreased in a range of the ratio of the hole density to the electron density of more than 100%.

The total amount of change in phase, obtained by multiplying the amount of change in phase per hole by the total amount of movement of carriers in the case where the predetermined modulation voltage was applied, was greater in a case where the ratio of the hole density to the electron density was more than 35% but less than 100%, as compared with a case where the ratio of the hole density to the electron density was 100%.

Therefore, it was found that in a case where asymmetrical doping is conducted so that the ratio of the hole density to the electron density is more than 35% but less than 100%, the semiconductor optical waveguide 10 in accordance with Example Group 3 is able to achieve further improvement of modulation efficiency as compared with a semiconductor optical waveguide 10 in which symmetrical doping is conducted.

### Embodiment 2

A semiconductor optical modulator 1 in accordance with Embodiment 2 of the present invention is described with reference to FIG. 7. Note that descriptions on members each identical to a member of the semiconductor optical waveguide 10 in accordance with Embodiment 1 will be omitted. FIG. 7 is a perspective view illustrating a configuration of the semiconductor optical modulator 1 in accordance with Embodiment 2.

The semiconductor optical modulator 1 modulates incident light by applying, to a p-n junction made of a semiconductor, a modulating electric field in accordance with a modulating signal. The semiconductor optical modulator 1 is a Mach-Zehnder (M-Z) optical modulator including the semiconductor optical waveguide described in Embodiment 1 on each of two arm sections constituting the Mach-Zehnder optical modulator.

(Configuration of Semiconductor Optical Modulator 1)

The semiconductor optical modulator 1 is a Mach-Zehnder semiconductor optical modulator 1 including an optical modulation section provided on at least one of two arm sections. The semiconductor optical modulator 1 includes, as the optical modulation section, a semiconductor optical waveguide (a first semiconductor optical waveguide 10a and a second semiconductor optical waveguide 10b) in accordance with one aspect of the present invention. Embodiment 2 employs a configuration in which optical modulation sections are provided on the respective two arm sections of the semiconductor optical modulator 1, and the semiconductor optical waveguide described in Embodiment 1 is provided as each of the optical modulation sections.

The semiconductor optical modulator 1 is fabricated with use of a single SOI substrate. The SOI substrate has a structure in which a lower Si layer 20, a BOX layer 19a, and an upper Si layer 19b are stacked. The BOX layer 19a of the SOI substrate is used as a lower clad in each of the semiconductor optical modulator 1, the first semiconductor optical waveguide 10a, and the second semiconductor optical waveguide 10b. Further, the upper Si layer 19b of the SOI substrate is processed into cores 22, 23, 24a, and 24b of the semiconductor optical modulator 1, a core of the first semiconductor optical waveguide 10a, and a core of the second semiconductor optical waveguide 10b.

The upper clad 19b is obtained by depositing SiO₂ over the lower clad 19a, the cores 22, 23, 24a, and 24b, the core of the first semiconductor optical waveguide 10a, and the core of the second semiconductor optical waveguide 10b. The upper clad 19b is provided so as to surround the lower clad 19a, the cores 22, 23, 24a, and 24b, the core of the first semiconductor optical waveguide 10a, and the core of the second semiconductor optical waveguide 10b.

Assuming that light is guided in the positive direction of the y-axis of the coordinate system shown in FIG. 7, the core 23 serves as a core on an incident side and the core 22 serves as a core on an exit side. The core 23 diverges into the core 24a, which is a first arm section, and the core 24b, which is a second arm section. The core 24a and the core 24b then converge into the core 22.

The first semiconductor optical waveguide 10a is inserted in a midway of the first arm section 24a, and the second semiconductor optical waveguide 10b is inserted in a midway of the second arm section 24b.

Two traveling-wave electrodes (the first electrode and the second electrode) included in the first semiconductor optical waveguide 10a are respectively connected to a signal line 16a and a signal line 18a which extend in a direction (the y-axis direction) in which light is guided. Similarly, two traveling-wave electrodes (the first electrode and the second electrode) included in the second semiconductor optical waveguide 10b are respectively connected to a signal line 16b and a signal line 18b.

A semiconductor optical modulation system in accordance with Embodiment 2 further includes a voltage source which applies a first modulation voltage to the signal line 16a and the signal line 18a and a second modulation voltage to the signal line 16b and the signal line 18b. The first modulation voltage and the second modulation voltage applied by the voltage source are each a modulation voltage in a reverse bias direction.

The semiconductor optical modulator 1 which is configured as described above provides similar effects as those of the semiconductor optical waveguide 10 described in Embodiment 1. Further, the semiconductor optical modulator 1 configured as described above can be fabricated by applying, on a single SOI substrate, the same process as that used for the fabrication of the semiconductor optical waveguide 10 described in Embodiment 1. That is, no new process is additionally needed in order to fabricate the semiconductor optical modulator 1. Therefore, the semiconductor optical modulator 1 can be fabricated at a similar cost as that required for the fabrication of the semiconductor optical waveguide 10 described in Embodiment 1.

### CONCLUSION

A semiconductor optical waveguide of the present invention includes a core which is a rib-slab type core including a rib and a pair of slabs, the core being divided, by a boundary surface included in the rib, into a p-type semiconductor region made of a p-type semiconductor and an n-type semiconductor region made of an n-type semiconductor, the boundary surface being constituted by (i) a first flat surface which serves as a junction surface of a first lateral p-n junction, wherein an upper end of the first flat surface reaches an upper surface of the rib, (ii) a second flat surface which serves as a junction surface of a vertical p-n junction, wherein a left end of the second flat surface is connected to a lower end of the first flat surface, and (iii) a third flat surface which serves as a junction surface of a second lateral p-n junction, wherein an upper end of the third flat surface is connected to a right end of the second flat surface and a lower end of the third flat surface reaches a lower surface of the rib.

As described above, the boundary surface (a junction surface of a p-n junction) between the p-type semiconductor region and the n-type semiconductor region has a crank-shape constituted by the first flat surface, the second flat surface, and the third flat surface, all of which are provided inside the rib.

According to the above configuration, a depletion layer formed near the junction surface of the p-n junction can be in a region closer to a center of the rib along the width of the rib, i.e., a region having a higher optical density, as compared with (i) a configuration illustrated in FIG. 1 of Patent Literature 2 in which the p-n junction has an L-shaped junction surface and (ii) a configuration illustrated in FIG. 2 of Patent Literature 2 in which the p-n junction has a crank-shaped junction surface.

This allows providing a semiconductor optical waveguide which has excellent high frequency characteristics like the configurations illustrated in FIGS. 1 and 2 of Patent Literature 2 and also has modulation efficiency better than those obtained with the configurations illustrated in FIGS. 1 and 2 of Patent Literature 2.

It is preferable to configure the semiconductor optical waveguide in accordance with one aspect of the present invention such that a distance between a left side surface of the rib and the first flat surface is not greater than 1.8 times a distance between the upper surface of the rib and the second flat surface.

In a case where the distance between the left side surface of the rib and the first flat surface is smaller than the distance between the upper surface of the rib and the second flat surface, it is possible to increase the total area of the junction surface of the p-n junction as compared with the configuration illustrated in FIG. 1 of Patent Literature 2 in which the p-n junction has an L-shaped junction surface. This allows an increase in volume of the depletion layer formed near the junction surface of the p-n junction and, accordingly, allows an increase in the number of carriers contributing to phase modulation.

In a case where the distance between the left side surface of the rib and the first flat surface is made further greater than the distance between the upper surface of the rib and the second flat surface, the junction surface of the p-n junction has a reduced total area as compared with a configuration in which of a p-n junction has an L-shaped junction surface. The reduction in total area of the junction surface means a reduction in volume of the depletion layer that is formed near the junction surface of the p-n junction. This results in a negative effect that the number of carriers contributing to phase modulation is decreased. On the other hand, increasing the distance between the left side surface of the rib and the first flat surface allows the first flat surface to be provided in a region having a higher optical density. This brings about a positive effect that the number of carriers contributing to phase modulation is increased.

In a case where the distance between the left side surface of the rib and the first flat surface is not greater than 1.8 times the distance between the upper surface of the rib and the second flat surface, the positive effect surpasses the negative effect, so that a half wavelength voltage Vpi can be suppressed as compared with a case in which a boundary surface between a p-type semiconductor region and an n-type semiconductor region is L-shaped (a configuration in which a first flat surface extends from a left end of a second flat surface to a left side surface of a rib). That is, improvement of modulation efficiency is achieved.

It is preferable to configure the semiconductor optical waveguide in accordance with one aspect of the present invention such that the distance between the left side surface of the rib and the first flat surface is not smaller than 1.1 times but not greater than 1.8 times the distance between the upper surface of the rib and the second flat surface.

As the distance between the left side surface of the rib and the first flat surface is increased, the total area of the boundary surface (the junction surface of the p-n junction) between the p-type semiconductor region and the n-type semiconductor region is reduced. The reduction in total area of the junction surface of the p-n junction suppresses a capacitance of the p-n junction, so that improvement of high frequency characteristics is achieved. It was in a case where the distance between the left side surface of the rib and the first flat surface was not smaller than 1.1 times the distance between the upper surface of the rib and the second flat surface that the high frequency characteristics were improved as compared with a configuration in which a p-n junction has an L-shaped junction surface.

Further, in a case where, as described above, the distance between the left side surface of the rib and the first flat surface was not greater than 1.8 times the distance between the upper surface of the rib and the second flat surface, improvement of modulation efficiency was achieved. Accordingly, both modulation efficiency and high frequency characteristics can be secured at higher levels according to the configuration in which the distance between the left side surface of the rib and the first flat surface is not smaller than 1.1 times but not greater than 1.8 times the distance between the upper surface of the rib and the second flat surface.

It is preferable to configure the semiconductor optical waveguide in accordance with one aspect of the present invention such that the second flat surface is positioned at a distance from a center of the rib, the center being contained in the p-type semiconductor region.

A configuration in which the second flat surface is positioned at a distance from the center of the rib along a height of the rib means that the distance between the upper surface of the rib and the second flat surface is different from the distance between the lower surface of the rib and the second flat surface. That is, the p-type semiconductor region and the n-type semiconductor region differ in thickness.

When combined with this configuration, a configuration in which the center of the rib is contained in the p-type semiconductor region means that the p-type semiconductor region has a thickness greater than that of the n-type semiconductor region.

Here, when amounts of change in phase are compared per carrier, an amount of change in phase of a p carrier (hole) is greater than an amount of change in phase of an n carrier (electron). Further, light guided in the rib-slab type core has an optical density which, along the height of the rib, becomes the highest at the center of the rib or at a portion of the rib which portion is below the center.

According to this configuration, the center of the rib or the portion of the rib below the center, where the optical density becomes the highest along the height of the rib, is contained in the p-type semiconductor region in which the amount of change in phase is greater than that in the n-type semiconductor region. This allows further improvement of modulation efficiency as compared with (i) a case in which the center of the rib is positioned on the second flat surface, which is a boundary surface between the p-type semiconductor region and the n-type semiconductor region and (ii) a case in which the center of the rib is contained in the n-type semiconductor region.

It is preferable to configure the semiconductor optical waveguide in accordance with one aspect of the present invention such that a distance between the center of the rib and the second flat surface is not smaller than 50% but not greater than 100% of a thickness of a depletion layer formed by a built-in potential.

As a carrier density changes by a greater amount according to a modulation voltage externally applied, an amount of optical phase shift increases. Near the boundary surface between the p-type semiconductor region and the n-type semiconductor region, an amount of change in carrier density is the greatest at a position near an outer side of a depletion layer that is formed by a built-in potential.

According to the above configuration, the center of the rib is located at a position near an outer side of the depletion layer, at which position a carrier density changes by a large amount. This enables further improvement of modulation efficiency.

It is preferable to configure the semiconductor optical waveguide in accordance with one aspect of the present invention such that a ratio of a hole density in the p-type semiconductor region to an electron density in the n-type semiconductor region is more than 35% but less than 100%.

The present inventors found that, as compared with a case in which the ratio of the hole density in the p-type semiconductor region to the electron density in the n-type semiconductor region is 100%, i.e., a case where the hole density in the p-type semiconductor region is equal to the electron density in the n-type semiconductor region, an increase in phase shift amount is achieved in a case where the ratio above is more than 35% but less than 100%. Therefore, according to the configuration above, further improvement of modulation efficiency is achieved.

It is preferable to configure the semiconductor optical waveguide in accordance with one aspect of the present invention such that a distance between a center of the rib and the second flat surface is not smaller than 50% but not greater than 200% of a thickness of a depletion layer formed by a built-in potential, in a case where the ratio of the hole density in the p-type semiconductor region to the electron density in the n-type semiconductor region is more than 35% but less than 100%.

In a case where the ratio of the hole density in the p-type semiconductor region to the electron density in the n-type semiconductor region is more than 35% but less than 100%, the depletion layer extends from the second flat surface toward an inside of the p-type semiconductor region, as compared with a case in which the hole density in the p-type semiconductor region is equal to the electron density in the n-type semiconductor region n-type semiconductor region.

As such, according to the above configuration, the center of the rib is located at a position near an outer side of the depletion layer, at which position a carrier density changes by a large amount. This enables further improvement of modulation efficiency.

It is preferable to configure the semiconductor optical waveguide in accordance with one aspect of the present invention such that the semiconductor optical waveguide further includes a clad surrounding the core, each of the p-type semiconductor region and the n-type semiconductor region being a semiconductor in which silicon is doped with a dopant or a semiconductor in which indium phosphide is doped with a dopant, the clad being made of any one of a semiconductor in which indium phosphide is doped with a dopant, silica, and air.

According to the above configuration, an existing semiconductor technology can be used to fabricate a semiconductor optical waveguide. This makes it possible to suppress cost for fabricating the semiconductor optical waveguide.

It is preferable to configure the semiconductor optical waveguide in accordance with one aspect of the present invention such that the semiconductor optical waveguide further includes: a first traveling-wave electrode connected to a first slab among the pair of slabs; and a second traveling-wave electrode connected to a second slab among the pair of slabs.

In a case where optical phase modulation is carried out with use of the semiconductor optical waveguide, the configuration above allows an increase in speed of the phase modulation operation.

A semiconductor optical modulator, which is a Mach-Zehnder semiconductor optical modulator, in accordance with one aspect of the present invention is preferably configured such that the semiconductor optical modulator includes an optical modulation section provided on at least one of arm sections, the optical modulation section being a semiconductor optical waveguide in accordance with one aspect of the present invention.

A semiconductor optical modulation system in accordance with one aspect of the present invention is preferably configured such that the semiconductor optical modulation system includes: a semiconductor optical modulator in accordance with one aspect of the present invention; and a voltage source applying, to each of the p-type semiconductor region and the n-type semiconductor region, a voltage in a reverse bias direction.

According to the above configuration, the semiconductor optical modulator in accordance with one aspect of the present invention and the semiconductor optical modulation system in accordance with one aspect of the present invention each bring about similar effects as those provided by the semiconductor optical waveguide of the present invention.

Note that the terms “upper end,” “lower end,” “right end,” and “left end” used in the Description simply mean ends that are respectively located on an upper side, a lower side, a right side, and a left side when a cross section of the semiconductor optical waveguide in accordance with the present invention is viewed from a particular direction, and do not limit a positional arrangement of the semiconductor optical waveguide.

The present invention is not limited to the embodiments, but can be altered by a skilled person in the art within the scope of the claims. An embodiment derived from a proper combination of technical means each disclosed in a different embodiment is also encompassed in the technical scope of the present invention.

### INDUSTRIAL APPLICABILITY

The present invention is applicable to a semiconductor optical waveguide which includes a core having a p-type semiconductor region and an n-type semiconductor region. The present invention is also applicable to a semiconductor optical modulator including the semiconductor optical waveguide, and a semiconductor optical modulation system including the semiconductor optical modulator.

### REFERENCE SIGNS LIST

1 semiconductor optical modulator
10 semiconductor optical waveguide
11 core (rib-slab type core)
12 rib
12a p-type semiconductor region
12b n-type semiconductor region
12J p-n junction
12S junction surface (boundary surface between
12J p-type semiconductor region and n-type semiconductor region)
12us upper surface
12bs lower surface
121s left side surface
12rs right side surface
13 first slab
14 second slab
15 and 17 first electrode and second electrode (traveling-wave electrode)
16 and 18 first signal line and second signal line
C center
J1 first p-n junction (first lateral p-n junction)
J2 second p-n junction (vertical p-n junction)
J3 third p-n junction (second lateral p-n junction)
S1, S2, and S3 first flat surface, second flat surface, and third flat surface
10a and 10b first phase modulation section and second phase modulation section (phase modulation section)

1. A semiconductor optical waveguide comprising a core which is a rib-slab type core including a rib and a pair of slabs,
the core being divided, by a boundary surface included in the rib, into a p-type semiconductor region made of a p-type semiconductor and an n-type semiconductor region made of an n-type semiconductor,
the boundary surface being constituted by (i) a first flat surface which serves as a junction surface of a first lateral p-n junction, wherein an upper end of the first flat surface reaches an upper surface of the rib, (ii) a second flat surface which serves as a junction surface of a vertical p-n junction, wherein a left end of the second flat surface is connected to a lower end of the first flat surface, and (iii) a third flat surface which serves as a junction surface of a second lateral p-n junction, wherein an upper end of the third flat surface is connected to a right end of the second flat surface and a lower end of the third flat surface reaches a lower surface of the rib.

2. The semiconductor optical waveguide as set forth in claim 1, wherein a distance between a left side surface of the rib and the first flat surface is not greater than 1.8 times a distance between the upper surface of the rib and the second flat surface.

3. The semiconductor optical waveguide as set forth in claim 2, wherein the distance between the left side surface of the rib and the first flat surface is not smaller than 1.1 times the distance between the upper surface of the rib and the second flat surface.

4. The semiconductor optical waveguide as set forth in claim 1, wherein the second flat surface is positioned at a distance from a center of the rib, the center being contained in the p-type semiconductor region.

5. The semiconductor optical waveguide as set forth in claim 4, wherein a distance between the center of the rib and the second flat surface is not smaller than 50% but not greater than 100% of a thickness of a depletion layer formed by a built-in potential.

6. The semiconductor optical waveguide as set forth in claim 4, wherein a ratio of a hole density in the p-type semiconductor region to an electron density in the n-type semiconductor region is more than 35% but less than 100%.

7. The semiconductor optical waveguide as set forth in claim 6, wherein a distance between a center of the rib and the second flat surface is not smaller than 50% but not greater than 200% of a thickness of a depletion layer formed by a built-in potential.

8. The semiconductor optical waveguide as set forth in claim 1, further comprising a clad surrounding the core,
each of the p-type semiconductor region and the n-type semiconductor region being a semiconductor in which silicon is doped with a dopant or a semiconductor in which indium phosphide is doped with a dopant,
the clad being made of any one of a semiconductor in which indium phosphide is doped with a dopant, silica, and air.

9. The semiconductor optical waveguide as set forth in claim 1, further comprising:
a first traveling-wave electrode connected to a first slab among the pair of slabs; and
a second traveling-wave electrode connected to a second slab among the pair of slabs.

10. A semiconductor optical modulator which is a Mach-Zehnder semiconductor optical modulator, comprising an optical modulation section provided on at least one of arm sections,
the optical modulation section being a semiconductor optical waveguide according to claim 1.

11. A semiconductor optical modulation system comprising:
a semiconductor optical modulator according to claim 10; and
a voltage source applying, to each of the p-type semiconductor region and the n-type semiconductor region, a voltage in a reverse bias direction.
